(19) United States
(12) Patent Application Publication
(10) Pub. No.: US 2026/0179658 A1
(43) Pub. Date: Jun. 25, 2026

(54) MEMORY DEVICE INCLUDING STACKED CONDUCTIVE CONTACTS

(71) Applicant: Micron Technology, Inc., Boise, ID (US)

(72) Inventors: Lifang Xu, Boise, ID (US); Aaron Yip, Los Gatos, CA (US)

(21) Appl. No.: 18/990,551

(22) Filed: Dec. 20, 2024

(51) Int. Cl. G11C 5/06; G11C 16/04; H10B 41/10; H10B 41/27; H10B 41/40

(52) U.S. Cl. CPC G11C 5/06; G11C 16/0483; H10B 41/10; H10B 41/27; H10B 41/40

(57) ABSTRACT

Some embodiments include apparatuses and methods of forming the apparatuses. One of the apparatuses includes: a first conductive material and a second conductive material located on different levels of the apparatus; a memory cell pillar extending through the first conductive material and the second conductive material; a first conductive contact coupled to a first conductive structure and coupled to the first conductive material at a first contact location; a second conductive contact coupled to a second conductive structure and coupled to the second conductive material at a second contact location. A direction from the first contact location to the first conductive structure is a first direction. A direction from the second contact location to the second conductive structure is a second direction. The first direction is opposite from the second direction.

### BACKGROUND

Dimensions of structures of some of the components in a memory device (e.g., a flash memory device) are relatively small (e.g., in nanometer size). At a certain dimension, structural damage (e.g., collapse) in part of the memory device may occur during fabrication. Such collapse can negatively affect yield, cost, performance, and reliability of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a memory device including a memory array and circuitries in different device structures, according to some embodiments described herein.

FIG. 3A shows a detailed schematic diagram of two blocks of the memory device of FIG. 2, according to some embodiments described herein.

FIG. 3B shows an example of the memory device of FIG. 3A including multiple drain select gates, according to some embodiments described herein.

FIG. 4 shows a top view of a structure of a portion of the memory device of FIG. 3A including a region of a memory array, a conductive contact region, and structures (e.g., slits) between the blocks of the memory device, according to some embodiments described herein.

FIG. 5A shows a side view (e.g., cross-section) of a structure of the memory device of FIG. 2, including tiers of materials that include respective memory cells and control gates associated with the memory cells, according to some embodiments described herein.

FIG. 5B shows a portion of the memory device of FIG. 5A including additional labels for respective elements of portions of the blocks of the memory device.

FIG. 6 shows a top view of the structure of a device structure of the memory device of FIG. 4 and FIG. 5A, including a region having conductive contacts and a region having memory cell pillars, according to some embodiments described herein.

FIG. 7A shows a side view (e.g., cross-section) of a portion of the memory device of FIG. 6, including stacked conductive contacts associated with control gates of the memory device, according to some embodiments described herein.

FIG. 7B and FIG. 7C show top views (e.g., cross-sections) along lines 7B and 7C, respectively, of a conductive contact of FIG. 7A, according to some embodiments described herein.

FIG. 8 shows a side view (e.g., cross-section) of a portion of a memory device that can be a variation of the memory device shown in FIG. 7A, according to some embodiments described herein.

FIG. 9 is a flowchart showing a method of forming a memory device, according to some embodiments described herein.

### DETAILED DESCRIPTION

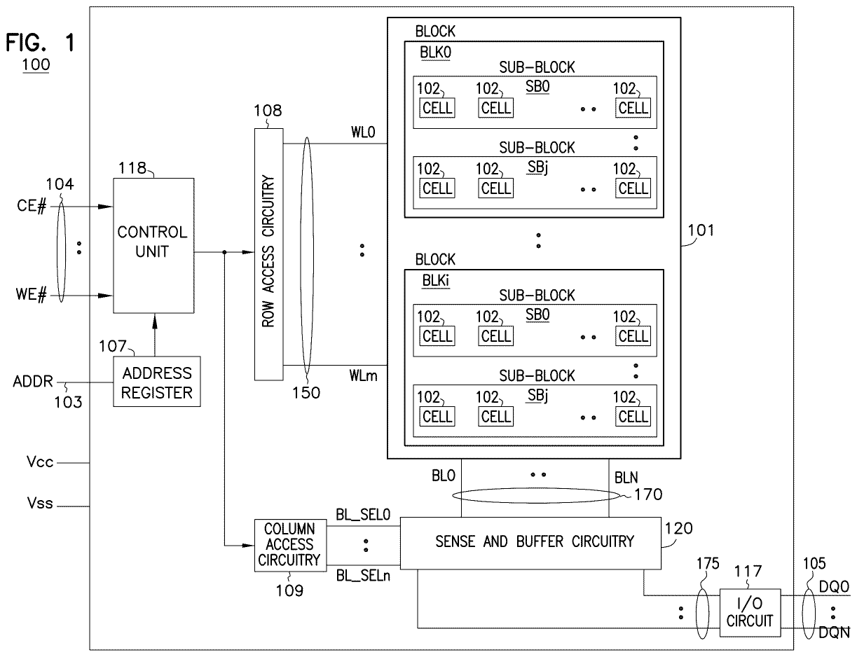

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. Signals (e.g., word line signals) can be provided to the control gates through the conductive contacts. In an example, the conductive contacts can be stacked one over another in a region of the memory device. As described in more detail below, the techniques described herein can improve at least one of yield, cost, performance, and reliability associated with the memory device. Other improvements and benefits of the techniques described herein are discussed below with reference to FIG. 1 through FIG. 8.

FIG. 1 shows a block diagram of an apparatus in the form of a memory device 100, according to some embodiments. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another).

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or to obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information that represents a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory.

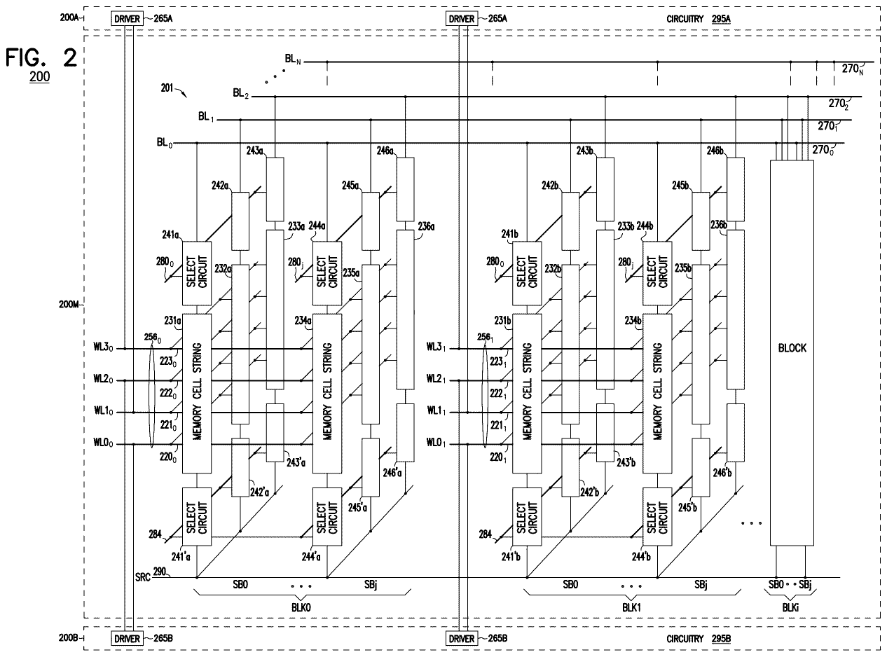

One of ordinary skill in the art may recognize that memory device 100 may include other components, several of which are not shown in FIG. 1, so as not to obscure the example embodiments described herein. At least a portion of memory device 100 can include structures and perform operations similar to or identical to the structures and operations of any of the memory devices described below with reference to FIG. 2 through FIG. 8.

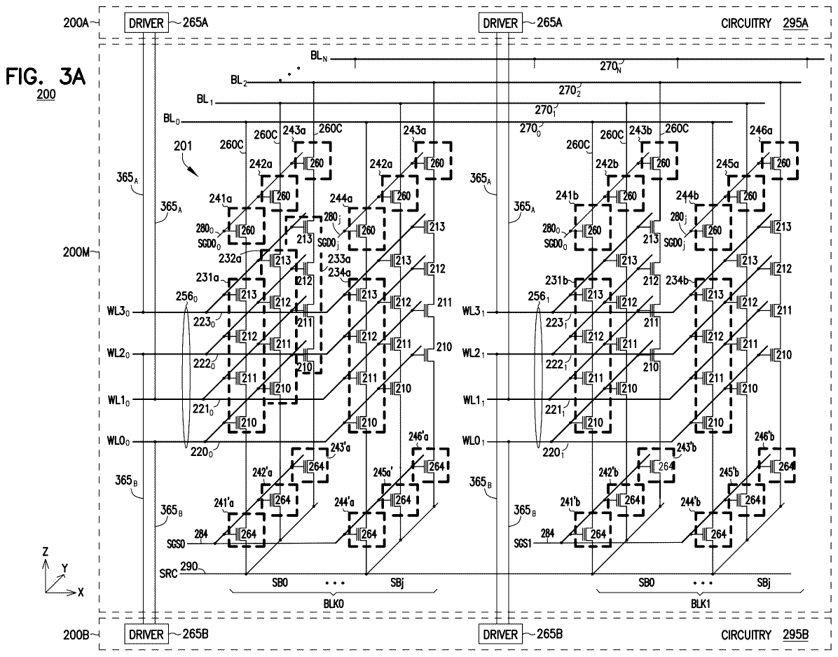

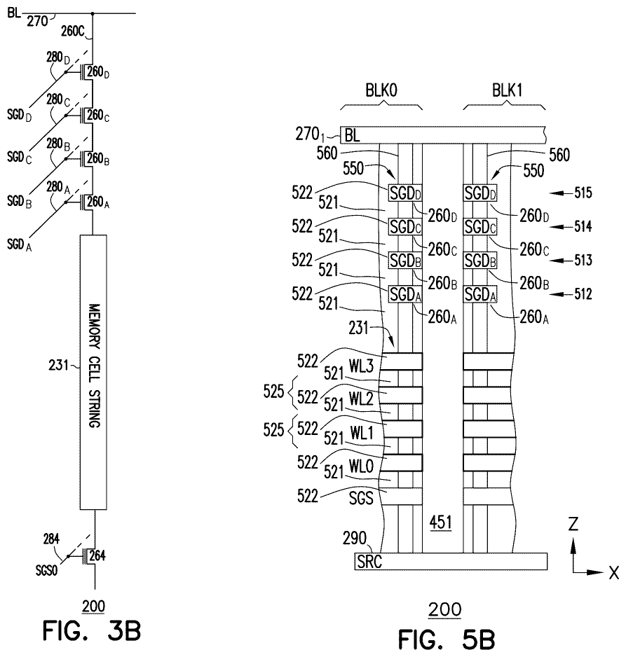

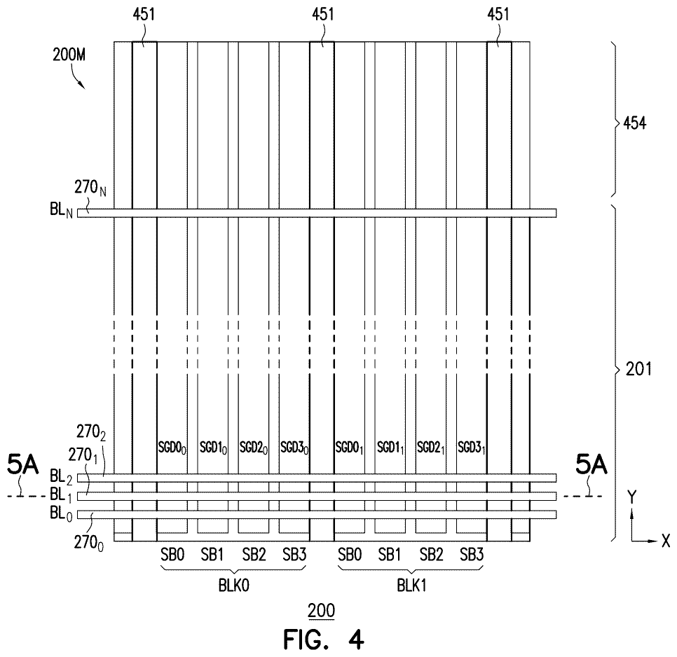

FIG. 2 shows a general schematic diagram of a memory device 200 including device structures 200A, 200B, and 200M according to some embodiments described herein. In the physical structure of memory device 200 (shown in FIG. 4 through FIG. 7A), each of device structures 200A, 200B, and 200M can include respective physical elements (e.g., memory cells and associated circuitry (e.g., string drivers) of memory device 200. In the figures showing schematic diagrams (e.g., FIG. 2, FIG. 3A, FIG. 3B) and the physical structure (FIG. 4 through FIG. 7A) of memory device, the same elements are labeled with the same reference labels (e.g., reference numbers).

As shown in FIG. 2, in device structure 200M, memory device 200 can include a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

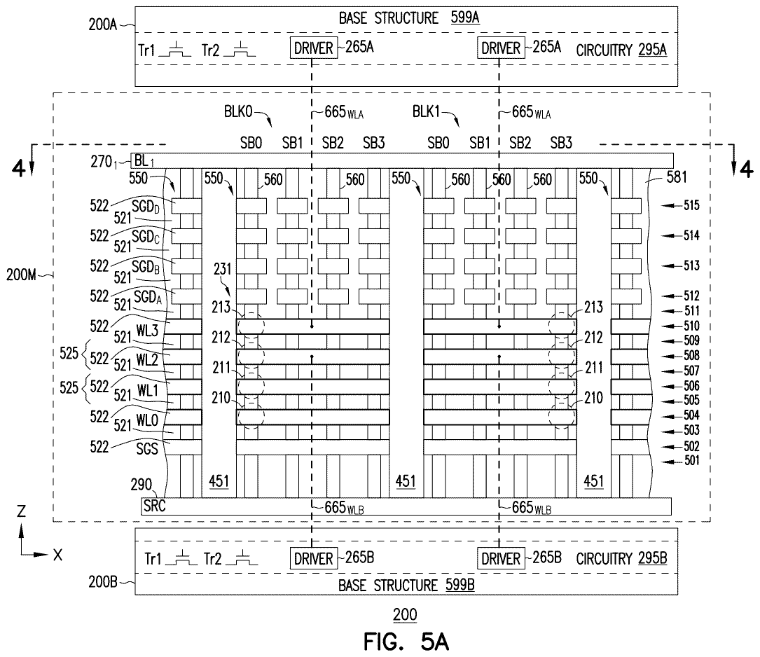

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A) and a pillar (e.g., pillar 550 in FIG. 5A) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

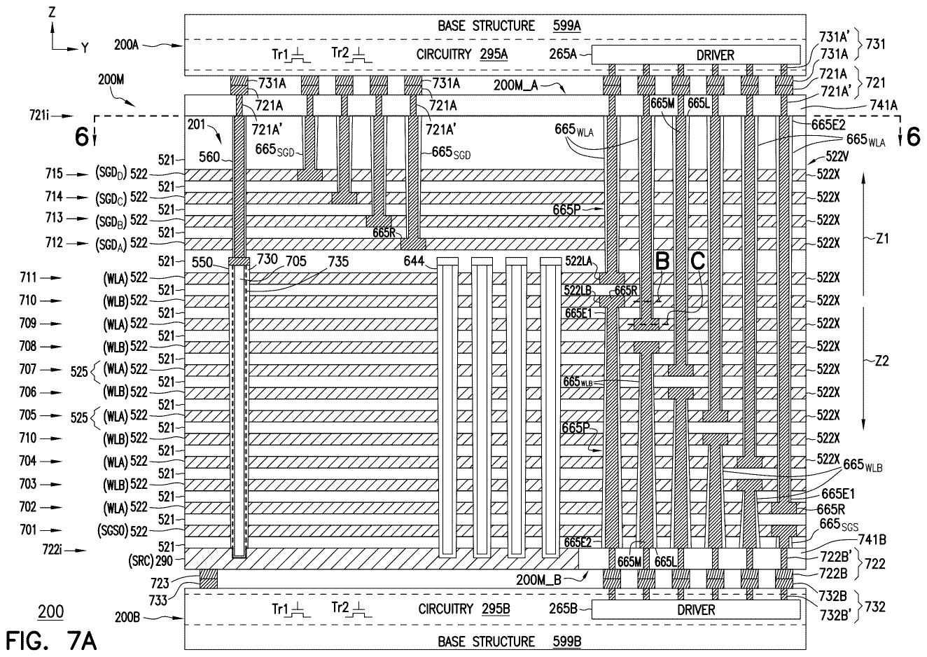

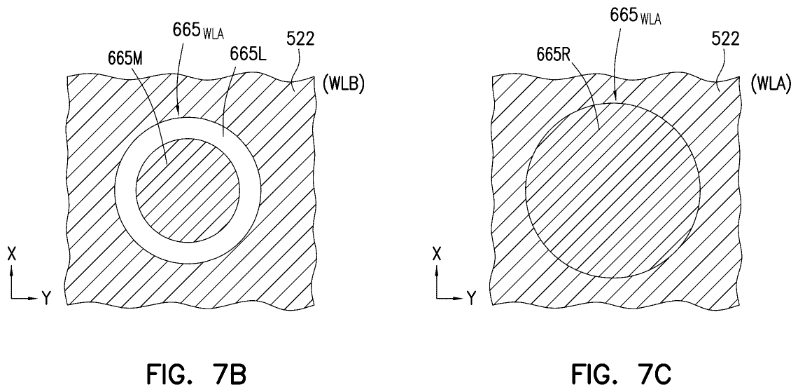

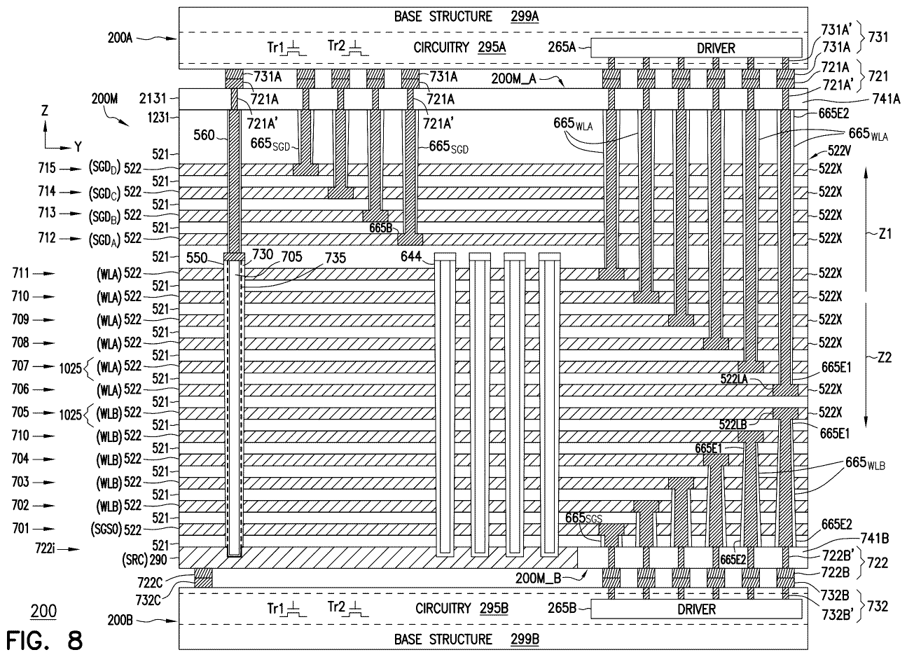

Each of control gates 220₀, 221₀, 222₀, and 223₀ can be part of a structure (e.g., a level) of a conductive material (e.g., a layer of conductive material), such as conductive material 522 in FIG. 5A and FIG. 7A, located on a physical level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Like block BLK0, each of control gates 220₁, 221₁, 222₁, and 223₁ in block BLK1 can be part of a structure (e.g., a level) of a conductive material (e.g., a layer of conductive material), such as conductive material 522 in FIG. 5 and FIG. 7A, located on a physical level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK0 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines (e.g., like four select lines 280_{A}, 280_{B}, 280_{C}, and 280_{D} in FIG. 3B) shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple-source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

As shown in FIG. 2, memory device 200 can include circuitry 295A and circuitry 295B located in device structures 200A and 200B, respectively. Circuitry 295A can include drivers (driver circuits) 265A. Circuitry 295A can include drivers (driver circuits) 265B. Each of drivers 265A and 265B can include a memory cell string driver circuit (e.g., word line driver circuit) of memory device 200. In a memory device like memory device 200, a driver (e.g., driver 265A or 265B) can provide signals (e.g., like signals WL0₀, WL1₀, WL2₀, and WL3₀, and signals WL0₁, WL1₁, WL2₁, and WL3₁) to control access to memory cells of a respective block.

For simplicity, FIG. 2 omits other elements and circuits of circuitry 295A and circuitry 295B, such as decoder circuits, buffers, sense amplifiers, charge pumps, and other circuits associated with a memory device (e.g., a NAND memory device) like memory device 200.

As shown in FIG. 2, driver 265A and 265B can be associated with (can be coupled to) a different a group (e.g., a subset) of control gates of a respective block. For example, for block BLK0, one of the driver circuits 265A can be coupled to the control gates associated with signals WL1₀ and WL3₀ of block BLK0. One of the driver circuits 265B can be coupled to the control gates the one associated with signals WL0₀ and WL2₀ of block BLK0.

In another example, for block BLK1, one of the driver circuits 265A can be coupled to the control gates associated with signals WL1₁ and WL3₁ of block BLK1. One of the driver circuits 265B can be coupled to the control gates associated with signals WL0₁ and WL2₁ of block BLK1.

Thus, as shown in FIG. 2, the control gates (associated with signals WL0₀, WL1₀, WL2₀, and WL3₀) of block BLK0 can be associated with drivers (e.g., drivers 265A and 265B) that are included in different device structures 200A and 200B. As shown in FIG. 2, the control gates (associated with signals WL0₁, WL1₁, WL2₁, and WL3₁) of block BLK1 can be associated with drivers (e.g., drivers 265A and 265B) that are included in different device structures 200A and 200B.

FIG. 3A shows a detailed schematic diagram including blocks BLK0 and BLK1 of memory device 200 of FIG. 2, according to some embodiments described herein. In FIG. 3A, device structures 200A, 200B, and 200M are the same as those shown in FIG. 2. As shown in FIG. 3A, the control gates associated with signals WL1₀ and WL3₀ of block BLK0 can be coupled to driver 265A through respective conductive connections 365_{A} (not labeled in FIG. 2). The control gates associated with signals W01₀ and WL2₀ of block BLK0 can be coupled to driver 265B through respective conductive connections 365_{B} (not labeled in FIG. 2).

In block BL1, the control gates associated with signals WL1₁ and WL3₁ of block BLK1 can be coupled to driver 265A through respective conductive connections 365_{B} (not labeled in FIG. 2). The control gates associated with signals Wl1₁ and WL2₁ of block BLK1 can be coupled to driver 265B through respective conductive connections 365_{B} (not labeled in FIG. 2).

In the physical structure of memory device 200 (shown in FIG. 7A), conductive connections 365_{A} and 365_{B} in FIG. 3A can include conductive contacts 665_{WLA} and 665_{WLB,} respectively (FIG. 7A).

In FIG. 3A, directions X, Y, and Z in FIG. 3A can be relative to the physical directions (e.g., three dimensional (3D) dimensions) of the structure of memory device 200. The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3A, similar drain select lines (and their associated signals) are given the same labels for simplicity. However, as shown in FIG. 3A, the drain select lines (from the same block or from different blocks) of memory device 200 are electrically separated from each other and carry different signals (although the signals are given the same labels).

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 5A and FIG. 7A) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds of memory cells (or more than hundreds of memory cells).

As shown in FIG. 3A, memory device 200 can include conductive connections 260C coupled between respective select gates 260 and respective data lines memory cells to respective data lines 270₀ through 270_{N}. In the physical structure of memory device 200, each conductive connection 260C can be part of a contact structure (e.g., contact structure 560 in FIG. 5A) associated with a memory cell pillar (e.g., pillar 550 in FIG. 5A) of memory device 200.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET includes an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer [e.g., a piece] or a region of conductive material) located in a single level of memory device 200. The conductive material can include metal, conductively doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor [e.g., FET]) between the portion of the conductive material and the portion of the channel material.

FIG. 3A shows an example where memory device 200 includes one drain select gate (e.g., select gate 260) in each drain select circuit, and one source select gate (e.g., select gate 264) in each source select circuit, coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows an example of memory device 200 including four select gates (e.g., four drain select gates) 260_{A}, 260_{B}, 260_{C}, and 260_{D} associated with four select lines 280_{A}, 280_{B}, 280_{C}, and 280_{D.} Memory device 200 can use signals SGD_{A}, SGD_{B}, SGD_{C}, and SGD_{D} on select lines 280_{A}, 280_{B}, 280_{C}, and 280_{D}, respectively, to control (turn on or turn off) select gates 260_{A}, 260_{B}, 260_{C}, and 260_{D}, respectively. Data line 270 and associated signal BL can be one of data lines 270₀ through 270_{N} associated with one of signals BL₀ through BL_{N}, respectively, in FIG. 3A. Memory cell string 231 (and associated conductive connection 260C) can be one of the memory cell strings (e.g., memory cell string 231a) associated with conductive connection 260C of memory device 200 of FIG. 3A.

The structures of select lines 280_{A}, 280_{B}, 280_{C}, and 280_{D} can be similar to or the same as those of the select lines associated with signals SGD_{A}, SGD_{B}, SGD_{C}, and SGD_{D} of memory device 200 shown in FIG. 7A. FIG. 3B shows one source select gate (e.g., select gate 264) and one source select signal (e.g., signal SGS0) on a source select line (e.g., select line 284). However, memory device 200 can include two or more source-select gates (in the Z-direction) like select gates 260_{A}, 260_{B}, 260_{C}, and 260_{D}.

FIG. 4 shows a top view of a structure of device structure 200M of memory device 200 of FIG. 2 and FIG. 3A, according to some embodiments described herein. As shown in FIG. 4, memory device 200 can include a region of memory array 201 including blocks BLK0 and BLK1, a region 454, and structures 451 between blocks. For simplicity, some elements of memory device 200 in one figure may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3A are also not repeated.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called a dielectric structure or a slit structures. The regions of memory device 200 at which structures 451 are located can be called slit regions.

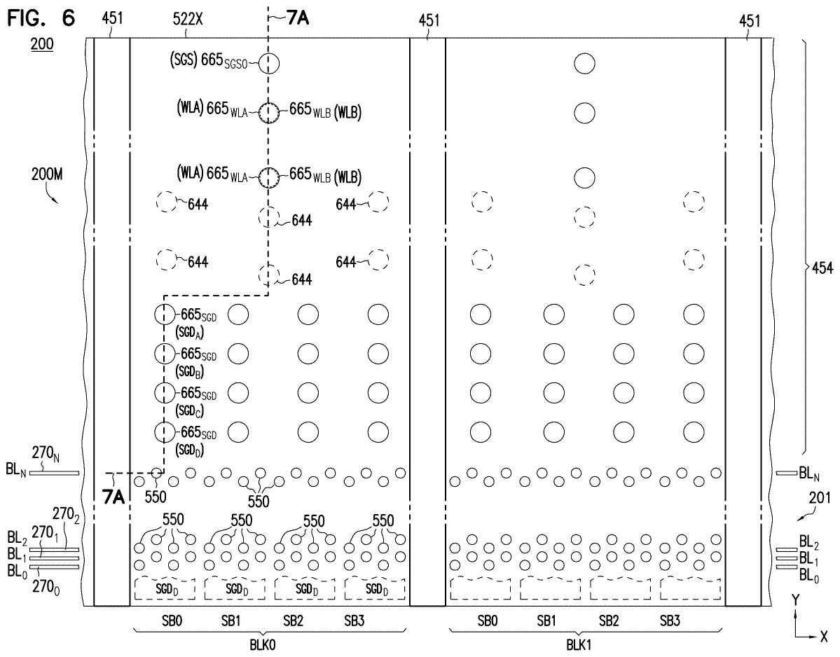

Region 454 can be called conductive contact region (e.g., word line contact region) of memory device 200. As described in more detail below, memory device 200 can include conductive contacts (e.g., contacts 665_{WLA} and 665_{WLB} in FIG. 5A, FIG. 6, and FIG. 7A) in region 454 that are coupled to respective control gates to provide respective signals to the control gates. The signals include signals WL0₀, WL1₀, WL2₀, and WL3₀ (FIG. 2 and FIG. 3A) associated with the control gates of block BLK0, and signals WL0₁, WL1₁, WL2₁, and WL3₁ (FIG. 2 and FIG. 3A) associated with the control gates of block BLK1.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include sub-blocks SB0, SB1, SB2, and SB3, and select lines (e.g., drain select lines) SGD0₁, SGD1₁, SGD2₁, and SGD3₁.

A side view side view (e.g., cross-section) at memory array (memory cell array) 201 of memory device 200 along line 5-5 in FIG. 4 is shown in FIG. 5A.

FIG. 5A shows a side view (e.g., cross-section) of a structure of a portion of memory device 200, according to some embodiments described herein. For simplicity, some structures (e.g., transistors Tr1 and Tr2, and drivers 265A and 265B of device structures 200A and 200B) of memory device 200 are shown as schematic symbols or boxes. In FIG. 5A, line 4-4 shows the location associated with the view (e.g., top view) of device structure 200M of memory device 200 of FIG. 4.

FIG. 5A shows blocks BLK0 and BLK1 and part of other blocks on the left and right sides of blocks BLK0 and BLK1 of device structure 200M of memory device 200. To avoid crowding FIG. 5A with labels, FIG. 5B shows a portion of memory device 200 of FIG. 5A that includes labels for a portion of block BLK0 and a portion of block BLK1.

As shown in FIG. 5A, in device structure 200M, memory device 200 can include levels 501 through 515 the Z-direction. Levels 501 through 515 are physical device levels of memory device 200. Memory device 200 can include a dielectric material 581 formed over at least a portion of memory device 200. Memory cells 210, 211, 212, and 213 of the memory cell strings (e.g., memory cell string 231 in FIG. 3B) of respective sub-blocks SB0, SB1, SB3, and SB3 of each of blocks BLK0 and BLK1 can be formed over source 290 (e.g., formed vertically in Z-direction in respective levels among levels 501 through 515). Source 290 can include a conductive material (or materials, e.g., different levels of different materials) and can have a length extending in the X-direction.

As shown in FIG. 5A, data line 270₁ (associated with signal BL₁) can extend in the X-direction across the blocks (e.g., blocks BLK0 and BLK1 and other blocks) of memory device 200. Data line 270₁ can be shared by respective memory cell strings (including memory cell string 231) of the blocks.

FIG. 5A and FIG. 5B shows data line 270₁ being included in device structure 200M as an example. However, data line 270₁ and other data lines (that are hidden from the view of FIG. 5A) of memory device 200 can be located in device structure 200A.

As shown in FIG. 5B, memory device 200 can include four select gates (e.g., four drain select gates) 260_{A}, 260_{B}, 260_{C}, and 260_{D} associated with a memory cell string (e.g., memory cell string 231). The other elements of memory device 200 of FIG. 5B can be the same as those of memory device 200 shown in FIG. 5A. Memory device 200 of FIG. 5B can represent the structure of memory device 200 that is schematically shown in FIG. 3B. FIG. 5B shows an example of memory device 200 including four select gates (e.g., four drain select gates) associated with signals SGD_{A}, SGD_{B}, SGD_{C}, and SGD_{D} in a respective sub-block (e.g., sub-block SB0, SB1, SB2, or SB3). Conductive materials 522 on respective levels 512, 513, 514, and 515 form the select lines (e.g., four select lines) associated with the select gates. Memory device 200 can include contact structures (e.g., data line contact structures) 560 associated with pillars (memory cell pillars) 550.

FIG. 5A and FIG. 5B show memory device 200 including four drain select gates (e.g., select gates 260_{A}, 260_{B}, 260_{C}, and 260_{D}) as an example. However, memory device 200 can include a different number of drain select gate associated with a memory cell string. FIG. 3A shows a schematic diagram of memory device 200 including one drain select gate (e.g., select gate 260) associated with a memory cell string (e.g., memory cell string 231a in FIG. 3A).

In FIG. 5A, the select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

In FIG. 5A, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 3A. In another example, in block BLK1 in FIG. 5A, the control gates indicated by signals WL0, WL1, WL2, and WL3 can correspond to respective control gates associated with signals WL0₁, WL1₁, WL2₁, and WL3₁, respectively, of block BLK1 shown in FIG. 3A.

As shown in FIG. 5A, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5A, dielectric materials 521 can be located on respective levels among levels 501 through 515. Conductive materials 522 can be located on respective levels (e.g., levels 502, 504, 506, 508, 510, 512, 513, 514, and 515) among levels 501 through 515. As shown in FIG. 5A, the levels of conductive materials 522 (e.g., in levels 501 through 511) are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., multi-layers of) aluminum oxide, titanium nitride, tungsten.

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

As shown in FIG. 5A, memory device 200 can include tiers 525. Tiers 525 are tiers of materials that form respective memory cells and control gates associated with the memory cells. The levels of dielectric materials 521 and the levels of conductive materials 522 can form tiers 525 of memory device 200. Each tier 525 can include a level of dielectric material 521 and a level of conductive material 522. For simplicity, only some of tiers 525 are labeled in FIG. 5A. As shown in FIG. 5A, tiers 525 can be located one over another and can include respective levels of memory cells 210, 211, 212, and 213, and control gates associated with the memory cells. FIG. 5A shows a few tiers (e.g., only two tiers 525 are labeled) of memory device 200 as an example. However, memory device 200 can include up to hundreds of tiers (or more than hundreds of tiers).

As shown in FIG. 5A, memory device 200 can include pillars (memory cell pillars) 550 in blocks BLK0 and BLK1. Each of pillars 550 can be part of a respective memory cell string (e.g., memory cell string 231). Each of pillars 550 can have length extending (e.g., extending vertically) in the direction of the Z-direction. As shown in FIG. 5A, the Z-direction is also a direction at which the length of pillar 550 extends from one tier to another tier, which is also a direction from levels of dielectric materials 521 to levels of conductive materials 522.

As shown in FIG. 5A, memory device 200 can include contact structures (e.g., data line contact structures) 560. Each pillar 550 can be coupled to a data line by a respective contact structure 560. Each contact structure 560 can be considered as part of a respective pillar 550 and can include a conductive material (or conductive materials) to allow electrical signal between pillar 550 and a respective data line.

As shown in FIG. 5A, memory cells 210, 211, 212, and 213 of respective memory cell strings (e.g., memory cell string 231) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

As shown in FIG. 5A, each of device structures 200A and 200B can include a base structure 599. Base structure 599 can include a base (e.g., a substrate). The base can include a semiconductor material (e.g., silicon). In device structure 200A, circuitry 295 can be adjacent (e.g., formed in or formed on) base structure 599. In device structure 200B, circuitry 295 can be adjacent (e.g., formed in or formed on) base structure 599 of device structure 200B. Each of circuitry 295A and 295B can include transistors (e.g., Tr1 and Tr2) that can be part of at least one of decoder circuits, buffers, sense amplifiers, charge pumps, and other circuitry of memory device 200.

As shown in FIG. 5A, in each of block BLK0 and BLK1, memory device 200 can include conductive contacts 665_{WLA} and 665_{WLB} coupled to respective control gate associated with signals WL2 and WL3 and respective drivers 265A and 265B. For simplicity, FIG. 5A shows conductive contact 665_{WLA} and contact 665_{WLA} as lines. For simplicity, FIG. 5A omits other conductive contacts (similar to conductive contact 665_{WLA} and contact 665_{WLA}) coupled to other control gates (associated with signals WL0 and WL1) of blocks BLK0 and BLK1 and respective drivers 265A and 265B. In the structure of memory device 200, conductive contact 665_{WLA} and contact 665_{WLA} are located in region 454 (FIG. 4 and FIG. 6) of device structure 200M of memory device 200. FIG. 7A, FIG. 7B, and FIG. 7C (described below) show detailed structure of conductive contact 665_{WLA} and contact 665_{WLA}.

FIG. 6 shows more details of a top view of a structure of memory device 200 of FIG. 4, according to some embodiments described herein. FIG. 6 shows the same view of device structure 200M of memory device 200 like FIG. 4. However, FIG. 6 shows more details of memory device 200 including the locations (in top view) of pillars 550 located in the region of memory array 201 of device structure 200M of memory device 200.

FIG. 6 also shows more details of memory device 200 including the locations (in top view) of conductive contacts 665_{WLA} and 665_{WLB}. Conductive contacts 665_{WLB} are shown dashed circles to indicate that conductive contacts 665_{WLB} can be located (e.g., formed) underneath (below) conductive contacts 665_{WLA} with respect to the Z-direction (as shown in FIG. 7A). Thus, the example of FIG. 6, conductive contacts 665_{WLA} can be stacked over (e.g., directly located over) conductive contacts 665_{WLB} (with respect to the Z-direction). However, conductive contacts 665_{WLA} can be stacked over conductive contacts 665_{WLB} (with respect to the Z-direction) but may not be directly stacked over conductive contacts 665_{WLB}.

FIG. 6 also shows more details of memory device 200 including the locations (top view) of conductive contacts 665_{SDG} and conductive contacts 665_{WLB}. FIG. 6 shows a particular pattern (e.g., the locations) and a particular number of conductive contacts 665_{WLA} and 665_{WLB} as an example. However, the pattern, the number, or both, of conductive contacts 665_{WLA} and 665_{WLB} can vary. For example, in FIG. 6, conductive contacts 665_{WLA} form a single row (from top view). However, conductive contacts 665_{WLA} can form multiple row next to each other in the X-direction.

Conductive contacts 665_{WL} can include metal (e.g., tungsten or other conductive materials). In FIG. 6, conductive contacts 665_{WLA} and 665_{WLB} can contact (form electrical connection with) respective control gates (associated with signals WLA and WLB) that are hidden from the top view of FIG. 6. In FIG. 6 (and FIG. 7A) signals WLA and WLB correspond to (represent) respective signals WL₀, WL1₀, WL2₀, and WL3₀, and signals WL0₁, WL1₁, WL2₁, and WL3₁ of FIG. 3A.

Conductive contacts 665_{WLA} and 665_{WLB} can be part of respective access lines (e.g., word lines) of memory device 200. Conductive contacts 665_{WLA} and 665_{WLB} in a respective block (e.g., block BLK0) allow signals (e.g., signals WLA and WLB) to be provided to respective control gates of the respective block (e.g., block BLK0) through conductive contacts 665_{WLA} and 665_{WLB}. FIG. 7A (described in more detail below) shows side views (e.g., cross-sections) of conductive contacts 665_{WLA} and 665_{WLB}. As shown in FIG. 6, each control gate (associated with one of signals WLA and WLB) in block BLK0 of FIG. 6 has an edge 522X. FIG. 6 shows one edge 522X to indicate that edges 522X (shown in FIG. 7A) may be aligned (e.g., vertically aligned) with each other in the Z-direction and are hidden from the top view of memory device 200 in FIG. 6.

As shown in FIG. 6, in region 454, memory device 200 can include a conductive contact (e.g., source select line contact) 665_{SGS0}. Conductive contact 665_{SGS0} in block BLK0 can contact (form electrical connection with) the source select line (e.g., select line 284 in FIG. 3A) of memory device 200 to provide signal SGS0 to the source select line of block BLK0.

As shown in FIG. 6, in region 454, memory device 200 can include conductive contacts (e.g., four drain select line contacts) 665_{SGD}. Conductive contact 665_{SGD0} in block BLK0 can contact (form electrical connection with) respective drain select lines (e.g., select lines 280_{A}, 280_{B}, 280_{C}, and 280_{D} in FIG. 3A) to provide respective signals SGD_{A}, SGD_{B}, SGD_{C}, and SGD_{D} to the drain select lines of block BLK0. In FIG. 6 shows one of the drain select lines (e.g., top drain select line (shown in dashed line) associated with signal 665_{SGD}) in a respective sub-block of block BLK0. The other drain select lines (e.g., select lines 280_{A}, 280_{B}, 280_{C}) are hidden from the top view of memory device 200 in FIG. 6.

As shown in FIG. 6, each of sub-blocks SB0, SB1, SB2, and SB3 can include multiple rows of pillars 550. The multiple rows of pillars 550 can be located one after another in the X-direction (rows having lengths parallel to the Y-direction). FIG. 6 shows an example where each sub-block includes four rows of pillars 550. However, the number of rows in the sub-blocks can be less than four or greater than four.

In FIG. 6, data lines 270₀ through 270_{N} are partially shown for simplicity. Data lines 270₀ through 270_{N} can extend across (in the X-direction) the blocks (e.g., blocks BL0 and BL1). Data lines 270₀ through 270_{N} can be located over and in electrical contact with pillars 550. Contact structures 560 (shown in FIG. 5A or FIG. 5B) coupled between pillars 550 and data lines 270₀ through 270_{N} are not shown in FIG. 6. Each pillar 550 in the same sub-block of a block can be coupled to a separate (e.g., unique) data line among data lines 270₀ through 270_{N}.

As shown in FIG. 6, memory device 200 can include dielectric pillars 644. FIG. 6 shows a particular the pattern (e.g., the locations) and a particular number of dielectric pillars 644 as an example. However, the pattern, the number, or both, dielectric pillars 644 can vary.

Each of dielectric pillars 644 can include a dielectric structure having lengths (shown in FIG. 7A) extending the Z-direction. Dielectric pillars 644 can include dielectric materials (silicon dioxide), non-dielectric materials (e.g., semiconductor materials or conductive materials), or a combination of dielectric materials and non-dielectric materials.

Dielectric pillars 644 can be formed to provide structural support to a portion (e.g., region 454) of device structure 200M of memory device 200 (e.g., support during part of the processes of forming device structure 200M of memory device 200).

Block BLK1 can include elements similar to those of block BLK1. For simplicity, the description of the structure of block BLK1 is omitted herein.

A side view (e.g., cross-section) along line 7A-7A in FIG. 6 of block BLK0 is shown in FIG. 7A.

FIG. 7A shows a side view of a portion of memory device 200 including conductive contacts 665_{WLA} and 665_{WLB}, 665_{SGD}, and 665_{SGS0} in region 454, and pillar 550 in memory array 201, according to some embodiments described herein. FIG. 7A also shows part of device structure 200A and 200B on opposite sides (in the Z-direction) of device structure 200M. Device structure 200M in FIG. 7A is the same as device structure 200M of FIG. 5A except for the higher number of tiers 525 in FIG. 7A. For example, FIG. 5A shows four tiers 525 of memory cells and control gates (associated with signals WL0, WL1, WL2, and WL3). FIG. 7A shows 10 tiers 525 of memory cells and control gates (associated with signals WL). In FIG. 7A, levels 701 through 711 can correspond to some of the levels (e.g., levels 502, 504, 506, 508, and 510) of FIG. 5A. Levels 712, 713, 714, and 715 of device structure 200M of FIG. 7A can correspond to levels 512, 513, 514, and 515, respectively, of device structure 200M of FIG. 5A.

As shown in FIG. 7A, device structure 200M can include a side 200M_A and 200M_B opposite from each other in the Z-direction. Device structures 200A and 200B can be located on and coupled to sides 200M_A and 200M_B, respectively. FIG. 7A also shows direction Z1 and direction Z2 opposite from each other with respect to the Z-direction. As shown in FIG. 7A, device structure 200M is between device structures 200A and 200B. A direction from 200M to device structure 200A is direction Z1. A direction from device structure 200M to device structure 200B is direction Z2.

Device structure 200M can include conductive structure 721 adjacent (e.g., formed on) side 200M_A of device structure 200M, and conductive structure 722 adjacent (e.g., formed on) side 200M_B of device structure 200M. Conductive structure 721 can include a conductive pad (e.g., metal pad) 721A and a conductive portion (e.g., conductive via) 721A′ coupled to (in electrical contact with) conductive pad 721A. Conductive structure 722 can include a conductive pad (e.g., metal pad) 722A and a conductive portion (e.g., conductive via) 722A′ coupled to (in electrical contact with) conductive pad 722A.

As shown in FIG. 7A, device structure 200M can include a dielectric portion (dielectric layer) 741A adjacent side 200M_A and a dielectric portion (dielectric layer) 741B adjacent side 200M_B. Conductive portion 721A′ can include a conductive material (or conductive materials) formed in a hole in dielectric portion 741A portion. Conductive portion 722A′ can include a conductive material (or conductive materials) formed in a hole in dielectric portion 741B portion.

Device structure 200A can also include conductive structure 723 adjacent side 200M_B and coupled to (in electrical contact with) source 290. Device structure 200B can include conductive structure 733 coupled to circuitry 295B of device structure 200B. As shown in FIG. 7A, conductive structure 722 of device structure 200M can be coupled to (in electrical contact with) conductive structure 733 of device structure 200B.

Device structure 200A can include conductive structure 731. Conductive structure 731 can include a conductive pad (e.g., metal pad) 731A and a conductive portion (e.g., conductive via) 731A′ coupled to (in electrical contact with) conductive pad 731A. As shown in FIG. 7A, conductive structure 721 of device structure 200M can be coupled to (in electrical contact with) conductive structure 731 of device structure 200A. For example, conductive pad 721A of conductive structure 721 can be coupled (e.g., can contact) conductive pad 731A of conductive structure 731. As shown in FIG. 7A, conductive structure 731 can be coupled to driver 265A. Thus, conductive structure 721 can be coupled to driver 265A through conductive structure 731.

Device structure 200B can include a conductive structure 732 Conductive structure 732 can include a conductive pad (e.g., metal pad) 732A and a conductive portion (e.g., conductive via) 732A′ coupled to (in electrical contact with) conductive pad 732A. As shown in FIG. 7A, conductive structure 722 of device structure 200M can be coupled to (in electrical contact with) conductive structure 732 of device structure 200B. For example, conductive pad 722B of conductive structure 722 can be coupled (e.g., can contact) conductive pad 732B of conductive structure 732. As shown in FIG. 7A, conductive structure 732 can be coupled to driver 265B. Thus, conductive structure 722 can be coupled to driver 265B through conductive structure 732.

As shown in FIG. 7A, dielectric pillars 644 can include respective lengths extending in the Z-direction through dielectric materials 521 and conductive materials 522 (e.g., extending through tiers 525). Dielectric pillars 644 can have the same lengths (e.g., same heights). Dielectric pillars 644 can land on (e.g., stop at) the material of source 290. However, dielectric pillars 644 are electrically separated (electrically decoupled from) source 290 and the control gates (associated with signals WL) and other elements (e.g., source 290) of memory device 200.

As shown in FIG. 7A, pillar 550 can extend through conductive materials 522 (which form the control gates and the select lines) and dielectric materials 521 in the portions that include memory array 201.

As shown in FIG. 7A, memory device 200 can include a structure 730 and a dielectric material 705 that can be part of pillar 550. Structure 730 can include multiple layers of different materials adjacent each other. For simplicity, details of the multiple layers are not shown in FIG. 7A. Structure 730 and a dielectric material 705 can extend continuously (in the Z-direction) along the length of the respective pillar 550. Dielectric material 705 can include silicon dioxide. Structure 730 of a respective pillar 550 in a block is adjacent portions of respective control gates of that block. For example, structure 730 of pillar 550 in block BLK0 is adjacent the control gates associated with signals WL0₀, WL1₀, WL2₀, and WL3₀, respectively. Structure 730 can be electrically coupled to a respective data line (e.g., one of data line 270₀ through 270_{N} in FIG. 3A and FIG. 6) and source 290. For example, structure 730 can be electrically coupled to a respective data line through contact structure 560. Structure 730 can be electrically coupled to source 290 through and a conductive structure (e.g., conductive channel) 735.

As shown in FIG. 7A, conductive structure 735 can contact source 290. Conductive structure 735 can be part of a conductive path (e.g., pillar channel structure) to conduct current between a respective data line (e.g., one of data line 270₀ through 270_{N} in FIG. 3A and FIG. 6) coupled to structure 730 and source 290.

Structure 730 can also include a material (or materials), which is not shown in detail in FIG. 7A, that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si (silicon) material can be part of the pillar channel structure of pillar 550. In another example, structure 730 include can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7A, the control gates associated with signals WLA and WLB and the select lines associated with signals (e.g., drain select signals and source select signal) SGD and SGS can be structured (e.g., patterned), such that they can have the same length in the Y-direction. For example, the control gates (formed from respective conductive materials 522) associated with signals WLA and WLB can have the same length (in the Y-direction) measuring between pillar 550 and edges 522X of respective the control gates. Edges 522X are part of respective conductive materials 522. As shown in FIG. 7A, the control gates associated with signals WLA and WLB can have the same length, such that edges 522X may be aligned (e.g., vertically aligned) with each other at a reference location (e.g., reference point), such as reference location 522V in the X-direction.

Thus, as shown in FIG. 7A, the conductive contacts (e.g., conductive contacts 665_{WLA} and 665_{WLB}, 665_{SGD}, and 665_{SGS}) can be between pillar 550 and edges 522X. For example, the conductive contact 665_{WLA} associated with the control gate on level 709 is between pillar 550 and edge 522X of conductive material 522 on level 709 and also between pillar 550 and edge 522X of conductive material 522 on level 711.

In another example, the conductive contact 665_{WLB} associated with the control gate on level 708 is between pillar 550 and edge 522X of conductive material 522 on level 708 and also between pillar 550 and edge 522X of conductive material 522 on level 710.

As shown in FIG. 7A, conductive contacts 665_{WLA} and 665_{WLB} can be divided into groups, such as a group including conductive contacts 665_{WLA} and a group including conductive contacts 665_{WLB}. Conductive contacts 665_{WLA} and 665_{WLB} can be stacked one group (e.g., the group including conductive contacts 665_{WLA}) over another group (e.g., the group including conductive contacts 665_{WLA}) in the Z-direction.

As shown in FIG. 7A, conductive contacts (e.g., word line contacts) 665_{WLA} and 665_{WLB} can include respective pillars (conductive pillars) 665P. Pillars 665P of the same group of conductive contacts (e.g., the group including conductive contacts 665_{WLA}) can have different (unequal) lengths extending in the Z-direction. Pillars 665P of two conductive contacts 665_{WLA} and 665_{WLB} directly stacked one over another can have also different (unequal) lengths extending in the Z-direction. The length of a particular conductive contact (e.g., conductive contact 665_{WLA} or 665_{WLB}) can also be length of its associated pillar 665P.

The length of a particular conductive contact 665_{WLA} can be a distance (the measurement) in the Z-direction from the control gate (e.g., from a contact location 522LA) associated with that particular conductive contact to a reference location (e.g., at level 721i) in device structure 200M of memory device 200. The length of a particular conductive contact 665_{WLB} can be a distance (the measurement) in the Z-direction from the control gate (e.g., from a contact location 522LB) associated with that particular conductive contact to a reference location (e.g., at level 722 i) in device structure 200M of memory device 200.

For example, the length of the conductive contact 665_{WLA} coupled to the control gate on level 711 can be the distance (the measurement) in the Z-direction from level 711 to level 721i. In another example, the length of the conductive contact 665_{WLB} coupled to the control gate on level 710 can be the distance (the measurement) in the Z-direction from level 710 to level 722i.

FIG. 7A shows contact locations 522LA and 522LB. Contact location 522LA is the location at which a particular conductive contacts 665_{WLA} contacts of conductive material 522 that forms the control gate associated with that particular conductive contacts 665_{WLA.} Contact location 522LB is the location at which a particular conductive contacts 665_{WLB} contacts conductive material 522 that forms the control gate associated with that particular conductive contacts 665_{WLB.}

Each of conductive contacts 665_{WLA} and 665_{WLB} can include an end portion (e.g., end segment) 665E1, and end portion (e.g., end segment) 665E2, and a portion (e.g., middle segment) between end portions 665E1 and 665E2.

Each of conductive contacts 665_{WLA} and 665_{WLB} can include a conductive landing pad 665R at an end portion 665E1. Conductive landing pad 665R contacts a respective control gate (associated with signal WLA or WLB) at a respective contact location 522LA or 522LB. As shown in FIG. 7A, conductive landing pad 665R of a respective conductive contact (conductive contact 665_{WLA} or conductive contacts 665_{WLB}) can have width (in the Y-direction) greater than the width (in the Y-direction) of pillar 665P of the respective conductive contact.

In the group of conductive contacts 665_{WLA}, end portion 665E1 of a respective conductive contact 665_{WLA} can contact a respective control gate (associated with signal WLA) at contact location 522LA. End portion 665E2 of a respective conductive contact 665_{WLA} can contact a respective conductive structure 721. As shown in FIG. 7A, direction Z1 is the direction from contact location 665LA associated with a particular conductive contacts 665_{WLA} to conductive structure 721 coupled to that particular conductive contacts 665_{WLA}.

In the group of conductive contacts 665_{WLB}, end portion 665E1 of a respective conductive contact 665_{WLB} can contact a respective control gate (associated with signal WLB) at contact location 522LB. End portion 665E2 of a respective conductive contact 665_{WLB} can contact a respective conductive structure 722. As shown in FIG. 7A, direction Z2 (opposite from direction Z1) is the direction from contact location 522LB associated with a particular conductive contacts 665_{WLB} to conductive structure 722 coupled to that particular conductive contacts 665_{WLB}.

As shown in FIG. 7A, the lengths (in the Z-direction) of conductive contact 665_{WLB} can decrease in the direction (X-direction) from pillar (memory cell pillar) 550 to edges 522X of conductive materials 522. For example, as shown in FIG. 7A, conductive contact 665_{WLB} coupled to the control gate (associated with signal WLB) on level 711 is closer (in the Y-direction) to pillar (memory cell pillar) 550 than conductive contact 665_{WLB} coupled to the control gate (associated with signal WLB) on level 708. In this example, the length of conductive contact 665_{WLB} coupled to the control gate on level 711 is greater than the length conductive contact 665_{WLB} coupled to the control gate on level 708.

As shown in FIG. 7A, each of conductive contacts 665_{WLA} and 665_{WLB} can include conductive material 665M (that forms pillar 665P) that extends through (e.g., goes through) respective portions of dielectric materials 521 and conductive materials 522. Each of conductive contacts 665_{WLA} and 665_{WLB} can include a liner (dielectric liner) 665L to separate (electrically isolate) a respective contacts 665_{WLA} or 665_{WLB} from conductive materials 522 except for one of the conductive material 522 that forms the control gate associated with the respective conductive contact.

As shown in FIG. 7A, conductive contacts 665_{SGD} and 665_{SGS} can include similar structures as conductive contacts 665_{WLA} and 665_{WLB}. Conductive contacts 665_{SGD} and 665_{SGS} can also be coupled to respective device structures 200A and 200B (e.g., through respective conductive structures 721 and conductive structure 722) in ways similar to that of conductive contacts 665_{SGD} and 665_{SGS}. Thus, for simplicity, detailed descriptions of conductive contacts 665_{SGD} and 665_{SGS} is omitted.

Different views (e.g., cross-sections) of pillar 665P of one of conductive contacts 665_{WLA} along lines 7B and 7C are shown in FIG. 7B and FIG. 7C, respectively.

FIG. 7B and FIG. 7C show top views (e.g., cross-sections) along lines 7B and 7C, respectively, of FIG. 7A, according to some embodiments described herein. As shown in FIG. 7B, conductive material 665M of pillar 665P of conductive contact 665_{WLB} is surrounded by liner 665L and is separated (electrically separated) from conductive material 522 associated with signal WLB. As shown in FIG. 7C, conductive landing pad 665R of conductive contact 665_{WLA} contacts (electrically coupled to) conductive material 522 associated with signal WLA.

FIG. 8 shows memory device 800, that can be a variations of memory device 200 of FIG. 7A, according to some embodiments described herein. As shown in FIG. 8, memory device 800A can include elements that are similar to or the same as the elements of memory device 200. For simplicity, descriptions of similar or the same elements between memory devices 200 and 800 are not repeated.

Differences between memory devices 200 and 800 include the pattern (e.g., physical arrangement) of conductive contact 665_{WLA}, 665_{WLB}, and 665_{SGS} contacts. For example, as shown in FIG. 7A, conductive landing pads 665R of conductive contacts 665_{WLA} may be adjacent (in the Z-direction) respective conductive landing pads 665R of conductive contacts 665_{WLB}. However, in FIG. 8, conductive landing pads 665R of conductive contacts 665_{WLA} may not be adjacent (in the Z-direction) respective conductive landing pads 665R of conductive contacts 665_{WLB}.

In another example, in FIG. 8, the conductive contacts within the same group of conductive contacts are coupled to the control gates that are adjacent each other. For example, as shown in FIG. 8, conductive contacts 665_{WLA} are coupled to the control gates (associated with signals WLA) that are adjacent each other. Conductive contacts 665_{WLB} are coupled to the control gates (associated with signals WLB) that are adjacent each other, as shown in FIG. 8.

In another example, the pattern of the connections between the conductive contacts and the control gates in FIG. 8 is different from that of FIG. 7A. In FIG. 7A, the lengths (in the Z-direction) of conductive contacts 665_{WLB} decrease in the direction (X-direction) from pillar (memory cell pillar) 550 to edges 522X of conductive materials 522. In FIG. 8, the lengths (in the Z-direction) of conductive contacts 665_{WLB} increase in the direction (X-direction) from pillar (memory cell pillar) 550 to edges 522X of conductive materials 522. For example, as shown in FIG. 8, conductive contact 665_{WLB} coupled to the control gate (associated with signal WLB) on level 702 is closer (in the Y-direction) to pillar (memory cell pillar) 550 than conductive contact 665_{WLB} coupled to the control gate (associated with signal WLB) on level 704. In this example, the length of conductive contact 665_{WLB} coupled to the control gate on level 704 is greater than the length conductive contact 665_{WLB} coupled to the control gate on level 702.

FIG. 7A and FIG. 8 show examples of the patterns of the conductive contacts 665_{WLA} and 665_{WLB} memory devices 200 and 800. However, the patterns of the conductive contacts of memory device 200 and 800 can be different from those shown in FIG. 7A and FIG. 8.

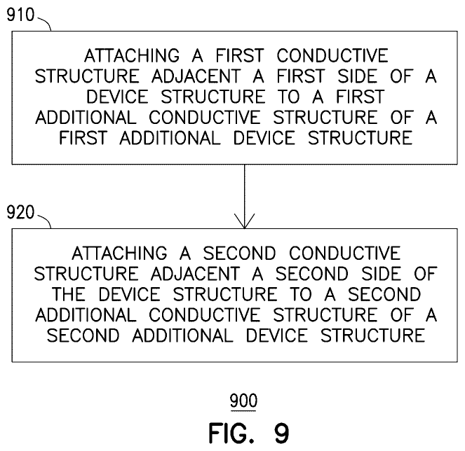

FIG. 9 is a flowchart showing a method 900 of forming a memory device, according to some embodiments described herein. The memory device associated with method can include memory device 200 or 800 described above with reference to FIG. 2 through FIG. 8.

As shown in FIG. 9, method 900 can include activities (e.g., processes) 910 and 920. Activity 910 can include attaching a first conductive structure (e.g., conductive structure 721) adjacent a first side of a device structure (e.g., device structure 200M) to a first additional conductive structure (e.g., conductive structure 731) of a first additional device structure (e.g., device structure 200A). Activity 920 can include attaching a second conductive structure adjacent a second side of the device structure to a second additional conductive structure of a second additional device structure. Activities 910 and 920 may be performed in any order. For example, activity 920 can be performed after to before activity 910 is performed. Method 900 can include fewer activities than activities 910 and 920. For example, either activity 910 or activity 920 may be omitted (not performed).

Memory devices 200 and 800 as described above can provide improvements and benefits in comparison to some alternative memory device structures. For example, in an alternative structure of memory device 200 or 800, conductive contacts 665_{WLA} and 665_{WLB} may not be stacked one group over another in the Z-direction. However, such an alternative structure may be susceptible to tier collapse or may need a relatively larger region (e.g., a region similar to region 454 in FIG. 6) for conductive contacts associated with the control gates of the alternative structure. A tier collapse may occur when the tiers (e.g., similar to tiers 525) of the memory device lack structural support during the process of forming the memory device.

The structure of memory device 200 or 800, including the described conductive contacts (e.g., conductive contacts 665_{WLA} and 665_{WLB}) allows memory device 200 or 800 to have a relatively small region (e.g., region 454 in FIG. 6) for conductive contacts associated with control gates of memory device 200 or 800. This can lead to improvement (reduction) in cost. Further, including conductive contacts like conductive contacts 665_{WLA} and 665_{WLB} in memory devices 200 or 800 can mitigate or prevent damage (e.g., tier collapse, tier bending, or both) in part of memory device 200 or 800 (e.g., at the locations of conductive contacts 665_{WLA} and 665_{WLB}) during processing. This can further improve yield and cost. Moreover, the absence of tier collapse and tier bending allows memory device 200 or 800 to maintain proper electrical connections between circuit elements (e.g., less susceptible to electrical short between circuit elements) of memory device 200 or 800. This can lead to improvement in at least one of performance and reliability of memory device 200 or 800.

The illustrations of apparatuses (e.g., memory devices 100, 200, and 800) and methods (e.g., method 900) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, and 800) or a system (e.g., a computer, a cellular phone, or other electronic systems) that includes a device such as any of memory devices 100, 200, and 800.

Any of the components described above with reference to FIG. 1 through FIG. 8 can be implemented in a number of ways, including simulation via software. Thus, apparatuses, e.g., memory devices 100, 200, and 800 or part of each of these memory devices described above, may all be characterized as “modules” (or “module”) herein. Such modules may include hardware circuitry, single-and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and range simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, and 800 may be included in apparatuses (e.g., electronic circuitry) such as high-speed computers, communication and signal processing circuitry, single-or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 [Motion Picture Experts Group, Audio Layer 3] players), vehicles, medical devices (e.g., heart monitor, blood pressure monitor, etc.), set top boxes, and others.

The embodiments described above with reference to FIG. 1 through FIG. 8 include apparatuses and methods of forming the apparatuses. One of the apparatuses includes: a first conductive material and a second conductive material located on different levels of the apparatus; a memory cell pillar extending through the first conductive material and the second conductive material; a first conductive contact coupled to a first conductive structure and coupled to the first conductive material at a first contact location; a second conductive contact coupled to a second conductive structure and coupled to the second conductive material at a second contact location. A direction from the first contact location to the first conductive structure is a first direction. A direction from the second contact location to the second conductive structure is a second direction. The first direction is opposite from the second direction. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third”, etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first conductive structure adjacent a first side of the apparatus;
a second conductive structure adjacent a second side of the apparatus;
a first conductive material located on a first level of the apparatus between the first side and the second side;
a second conductive material located on a second level of the apparatus between the first side and the second side;
a memory cell pillar extending through the first conductive material and the second conductive material;
a first conductive contact coupled to the first conductive structure and coupled to the first conductive material at a first contact location; and
a second conductive contact coupled to the second conductive structure and coupled to the second conductive material at a second contact location, wherein:
a direction from the first contact location to the first conductive structure is a first direction;
a direction from the second contact location to the second conductive structure is a second direction; and
the first direction is opposite from the second direction.

2. The apparatus of claim 1, further comprising:
a third conductive structure adjacent the first side of the apparatus;
a third conductive material located on a third level of the apparatus between the first conductive material and the second conductive material; and
a third conductive contact coupled to the third conductive structure and the third conductive material.

3. The apparatus of claim 1, further comprising:
a third conductive structure adjacent the first side of the apparatus;
a third conductive material located on a third level of the apparatus, wherein the second conductive material on the second level is between the first conductive material on the first level and the third conductive material on the third level; and
a third conductive contact coupled to the third conductive structure and the third conductive material.

4. The apparatus of claim 3, further comprising:
a fourth conductive structure adjacent the second side of the apparatus;
a fourth conductive material located on a fourth level of the apparatus, wherein the third conductive material on the third level is between the second conductive material on the second level and the fourth conductive material on the fourth level; and
a fourth conductive contact coupled to the fourth conductive structure and the fourth conductive material.

5. The apparatus of claim 1, further comprising:
a third conductive structure adjacent the second side of the apparatus;
a third conductive material located on a third level of the apparatus; and
a third conductive contact coupled to the third conductive structure; and
the third conductive material, wherein the first conductive contact is closer to the memory cell pillar than the third conductive contact and second conductive contact has a length greater than a length of the third conductive contact.

6. The apparatus of claim 5, further comprising:
a fourth conductive structure adjacent the first side of the apparatus;
a fourth conductive material located on fourth level of the apparatus; and
a fourth conductive contact coupled to the fourth conductive structure and the fourth conductive material, wherein the first conductive contact is closer to the memory cell pillar than the fourth conductive contact, and the fourth conductive contact has a length greater than a length of the first conductive contact.

7. The apparatus of claim 1, further comprising:
a third conductive structure adjacent the first side of the apparatus;
a fourth conductive structure adjacent the second side of the apparatus;
a third conductive material located on a third level of the apparatus;
a fourth conductive material located on fourth level of the apparatus;
a third conductive contact coupled to the third conductive structure and the third conductive material, wherein the first conductive contact is closer to the memory cell pillar than the third conductive contact, and the first conductive contact has a length greater than a length of the third conductive contact; and
a fourth conductive contact coupled to the fourth conductive structure and the fourth conductive material, wherein the second conductive contact is closer to the memory cell pillar than the fourth conductive contact, and the fourth conductive contact has a length greater than a length of the second conductive contact.

8. The apparatus of claim 1, wherein the first conductive material and the second conductive material have a same length.

9. The apparatus of claim 1, further comprising a first dielectric pillar adjacent the first conductive contact, a second dielectric pillar adjacent the first dielectric pillar, wherein the first dielectric pillar and the second dielectric pillar have a same length.

10. An apparatus comprising:
a device structure including:
a first conductive structure adjacent a first side of the apparatus;
a second conductive structure adjacent a second side of the apparatus;
a first control gate located on a first level of the apparatus between the first side and the second side;
a second control gate located on a second level of the apparatus between the first side and the second side;
a memory cell pillar associated with the first control gate and the second control gate, the memory cell pillar extending in a direction from the first control gate to the second control gate;
a first conductive contact coupled to the first conductive structure and the first control gate;
a second conductive contact coupled to the second conductive structure and the second control gate;
an additional device structure including circuitry; and
a first additional conductive structure coupled to the circuitry and the first conductive structure, wherein first conductive structure and the first additional conductive structure are between the circuitry and the first conductive contact.

11. The apparatus of claim 10, wherein the additional device structure includes a semiconductor base adjacent the circuitry, and the circuitry is between the semiconductor base and the first conductive structure of the device structure.

12. The apparatus of claim 10, further comprising:
a third conductive structure adjacent the first side of the apparatus;
a third control gate located on a third level of the apparatus, wherein the second level is between the first level and third level; and
a third conductive contact coupled to the third conductive structure and the third control gate.

13. The apparatus of claim 12, further comprising:
a fourth conductive structure adjacent the second side of the apparatus;
a fourth control gate located on a fourth level of the apparatus, wherein the third level is between the second level and fourth level; and
a fourth conductive contact coupled to the fourth conductive structure and the fourth control gate.

14. The apparatus of claim 10, wherein the apparatus comprises a memory device, and the circuitry includes a driver circuit coupled to the first additional conductive structure.

15. The apparatus of claim 10, wherein the additional device structure is a first additional device structure, and the apparatus further comprising a second additional device structure, the second additional device structure including:
an additional circuitry; and
a second additional conductive structure coupled to the additional circuitry and the second conductive structure, wherein the second conductive structure and the second additional conductive structure are between the additional circuitry and the second conductive contact.

16. The apparatus of claim 15, wherein the additional circuitry include an additional driver circuit coupled to second additional conductive structure.

17. The apparatus of claim 15, wherein the second additional device structure includes an additional semiconductor base adjacent the additional circuitry, and the additional circuitry is between the additional semiconductor base and the second conductive structure of the device structure.

18. A method comprising:
attaching a first conductive structure adjacent a first side of a device structure to an additional conductive structure of an additional device structure, wherein the device structure includes:
a second conductive structure adjacent a second side of the device structure;
a first control gate located on a first level of the device structure between the first side and the second side;
a second control gate located on a second level of the device structure between the first side and the second side;
a memory cell pillar associated with the first control gate and the second control gate, the memory cell pillar extending in a direction from the first control gate to the second control gate;
a first conductive contact coupled to the first conductive structure and coupled to the first control gate at a first contact location; and
a second conductive contact coupled to the second conductive structure and coupled to the second control gate at a second contact location, wherein:
a direction from the first contact location to the first conductive structure is a first direction;
a direction from the second contact location to the second conductive structure is a second direction; and
the first direction is opposite from the second direction.

19. The method of claim 18, wherein the additional device structure is a first additional device structure, an additional conductive structure is a first additional conductive structure, and the method further comprising:
attaching a second conductive structure adjacent a second side of the device structure to a second additional conductive structure of a second additional device structure.

20. The method of claim 19, wherein at least one of the first additional device structure and the second additional device structure includes a semiconductor base, and a driver circuit adjacent the semiconductor base and coupled to one of the first additional conductive structure and the second additional conductive structure.
